(19) United States
(12) Patent Application Publication
(10) Pub. No.: US 2019/0194794 A1
(43) Pub. Date: Jun. 27, 2019

(54) CERAMIC COLORING METHOD AND A CERAMIC PIECE FOR ELECTRONIC PRODUCTS

(71) Applicant: AAC Technologies Pte. Ltd., Singapore city (SG)

(72) Inventors: Jie He, Shenzhen (CN); Lei Dai, Shenzhen (CN)

(21) Appl. No.: 16/102,111

(22) Filed: Aug. 13, 2018

(30) Foreign Application Priority Data
Dec. 25, 2017 (CN) 201711418698.9

(51) Int. Cl. C23C 14/00; C23C 14/35; C25D 11/14; C23C 14/08

(52) U.S. Cl. CPC C23C 14/0015; C23C 14/081; C25D 11/14; C23C 14/35

(57) ABSTRACT

The present disclosure relates to a ceramic coloring method and a ceramic piece for electronic products. The ceramic coloring method comprises: providing a ceramic base material; plating, wherein an aluminum-containing metal film is plated on a surface of the ceramic base material; and coloring, wherein anodic oxidation coloring is performed to the aluminum-containing metal film. The electronic product ceramic piece comprises: a ceramic base material and an aluminum-containing metal film, the aluminum-containing metal film is plated on a surface of the ceramic base material, and the aluminum-containing metal film is colored by anodic oxidation. The ceramic coloring method and the ceramic piece for electronic product provided by the present disclosure are rich in colors and have a high-quality sample color effect.

### CROSS-REFERENCE TO RELATED APPLICATIONS

This application claims the priority benefit of Chinese Patent Application Ser. No. 201711418698.9 filed on Dec. 25, 2017, the entire content of which is incorporated herein by reference.

### FIELD OF THE PRESENT DISCLOSURE

The disclosure relates to the field of manufacturing, and more particularly, to a ceramic coloring method and a ceramic piece for electronic products.

### DESCRIPTION OF RELATED ART

Plastic materials are commonly used in shells of mobile communication terminal products. With the update and iteration of products, metal materials are obviously better than the plastic materials no matter from the aspect of texture or scratch resistance, so that the metal materials once replace the plastic materials and become the mainstream of shell materials. However, under the big circumstance of gradually entering the 5G communication era, the maturely applied technology of a metal shell and nanometer injection molding at current cannot satisfy the requirements of 5G signals. Glass and pottery shells have excellent signal penetrability, and are more beneficial for solving the signal problems of mobile communication terminal products when being used as the shell materials. However, the glass has lower strength, and is easy to break while falling. Therefore, the ceramic becomes the shell material of the mobile communication terminal products with most application prospect.

However, the colors of the ceramic are monotonous, which are mostly black and white, and cannot meet the requirement on diversity of product colors. In order to obtain colorful ceramic, a general method is to add a color material to a ceramic body. However, the sintering temperature of the ceramic is higher, which ranges from 1350 to 1650° C. in general. At the temperature, most of the color materials will be decomposed and volatilized to lose the coloring effect or the color thereof is weakened. In addition, coloring may also be performed by means of color spraying on the surface of the ceramic, but it is discovered by practices that a high-quality sample color effect cannot be obtained by all these methods.

### SUMMARY

The present disclosure aims at providing a ceramic coloring method and a ceramic piece for electronic products. The method can make the ceramic have a high-quality sample color effect.

In order to solve the technical problem above, the present disclosure provides a ceramic coloring method, which comprises the steps of: providing a ceramic base material; plating, wherein an aluminum-containing metal film is plated on a surface of the ceramic base material; and coloring, wherein anodic oxidation coloring is performed to the aluminum-containing metal film.

Preferably, the aluminum-containing metal film is made of aluminum or aluminum alloy.

Preferably, the plating is performed by magnetron sputtering physical vapor deposition.

Preferably, before the step of plating, the ceramic coloring method further comprises: preprocessing steps of deoiling, neutralizing and washing the provided ceramic base material, a step of baking the preprocessed ceramic base material at a temperature of 150 to 220° C., and a step of performing ionic cleaning to the baked ceramic base material in a vacuum state above 5*10⁻³ Pa.

Preferably, after completing the step of ionic cleaning, plating is performed in a vacuum state above 5*10⁻⁴ Torr, wherein a plating temperature is 230 to 250° C.

Preferably, the vacuum state of the step of ionic cleaning is 2*10⁻¹ to 6*10⁻¹ Pa.

Preferably, the vacuum state of the step of plating is 10⁻³ to 10⁻² Torr.

Preferably, a thickness of the aluminum-containing metal film is 30 to 40 μm.

Preferably, before the step of coloring, the ceramic coloring method further comprises: forming an anti-fingerprint plating layer on the surface of the aluminum-containing metal film colored by anodic oxidation.

The present disclosure further provides a ceramic piece for electronic products, which comprises: a ceramic base material and an aluminum-containing metal film, wherein the aluminum-containing metal film is plated on a surface of the ceramic base material, and the aluminum-containing metal film is colored by anodic oxidation.

Preferably, a thickness of the aluminum-containing metal film is 30 to 40 μm.

Preferably, the ceramic base material is made of yttria-stabilized zirconia.

Compared with the prior art, the present disclosure colors the aluminum-containing metal film by anodic oxidation through plating the aluminum-containing metal film on the surface of the ceramic base material, which can obtain different colors in the appearance surface of the ceramic base material and has a high-quality sample color effect.

### BRIEF DESCRIPTION OF THE DRAWINGS

FIG. 1 is a flow chart of a ceramic coloring method provided by the present disclosure; and

FIG. 2 is a schematic diagram illustrating a cross-sectional structure of a ceramic piece for electronic products provided by the present disclosure.

### DETAILED DESCRIPTION OF THE EXEMPLARY EMBODIMENTS

In order to make the objects, technical solutions and advantages of the embodiments of the disclosure clearer, the embodiments of the disclosure will be further described in detail hereinafter with reference to the accompanying drawings. However, those of ordinary skills in the art can understand that many technical details are proposed in the embodiments of the disclosure for readers to better understand the disclosure. However, the technical solutions sought to be protected by the disclosure can be implemented even without these technical details and various changes and modifications based on the following embodiments.

The implementation details of the ceramic coloring method of the embodiments will be specifically described hereinafter. The following contents are merely implementation details provided for ease of understanding, but are not essential to implement the solutions.

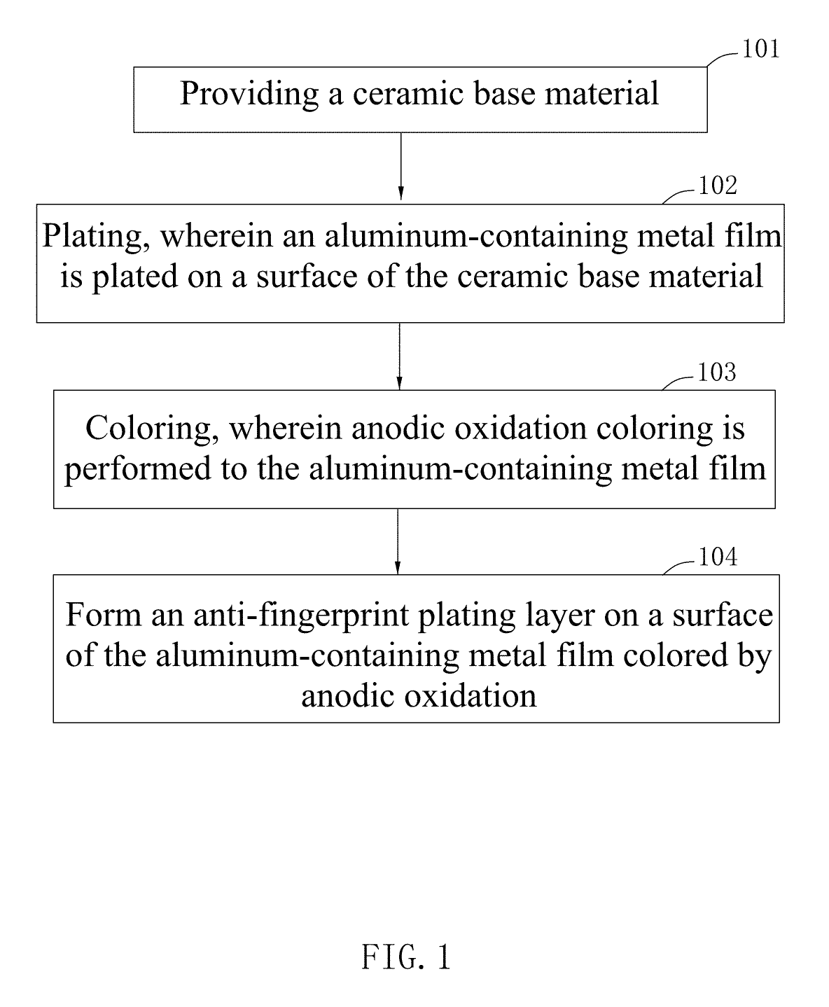

As shown in FIG. 1, the ceramic coloring method of the present disclosure comprises the following steps.

In step 101, providing a ceramic base material.

Specifically, providing a ceramic piece needing to be colored, i.e., a ceramic product to be processed or a certain ceramic piece/member (as long it is made of a ceramic material), and the ceramic piece is used as a base material to realize coloring at a later stage. It can be understood that, some preprocessing steps can be performed to the provided ceramic base material before coloring, to deoil, neutralize and wash the provided ceramic base material. During washing, the washing temperature is preferably controlled between 50 and 60° C., in this way, particles, dirt, stains, or acid-base substances remained on the surface of the ceramic base material can be better removed, so that the final coloring result cannot have a flaw due to the particles, dirt, stains, or acid-base substances on the surface of the ceramic base material in plating and coloring processes at a later stage. Certainly, the preprocessing steps above are preferable only, and the implementation of the embodiment cannot be affected even without the processing above.

In step 102, plating, wherein an aluminum-containing metal film is plated on a surface of the ceramic base material.

It should be noted that, the aluminum-containing metal film may be aluminum or aluminum alloy. In the embodiment, a thickness of the aluminum-containing metal film finally plated on the ceramic base material is preferably 30 to 40 μm. It is worth to mention that the aluminum-containing metal film of this thickness can already have good strength and scratch resistance, can protect the ceramic base material well when the aluminum-containing metal film is covered on the ceramic base material, and does not look too thick in the meanwhile. It should be noted that, the aluminum-containing metal film above may also be of other thicknesses, and is not limited to the example above.

There are a plurality of modes of plating the aluminum-containing metal film on the ceramic base material, and physical vapor deposition is used in the embodiment. Since the physical vapor deposition merely changes the material form, and does not involve in a chemical reaction, the technology is relatively simple, and a new chemical impurity that is difficult to be removed will not be generated. Moreover, the aluminum-containing metal film plated by physical vapor deposition is uniform and dense, and has a strong binding force with the ceramic base material. Preferably, the aluminum-containing metal film is deposited on the ceramic base material by magnetron sputtering in the embodiment. Specifically, the preprocessed ceramic base material is plated by a magnetron sputtering film plating machine.

In addition, it should be noted that, in order to make the aluminum-containing metal film be better deposited on the ceramic base material, before the step of plating, the preprocessed ceramic base material may be baked at a temperature of 150 to 220° C. firstly, and ionic cleaning is performed to the baked ceramic base material in a vacuum state above 5×10⁻³ Pa for 15 min, and the vacuum state of ionic cleaning is preferably 2×10⁻¹ to 6×10⁻¹ Pa.

After completing the step of ionic cleaning, the plating is performed in a vacuum state above 5×10⁻⁴ Torr, a plating temperature is 230 to 250° C., and the vacuum state of plating is preferably 10⁻³ to 10⁻² Torr. A vacuum degree during the plating process is controlled by a mixed gas flow of argon and oxygen in the embodiment. A flow ratio of the mixed gas of argon and oxygen is preferably 6 to 4.

In order to illustrate the implementation details of the embodiment more specifically, some specific parameters when depositing the aluminum-containing metal film on the ceramic base material by magnetron sputtering in the embodiment are listed as follows.

Process Parameters of AL film plating
process by magnetron sputtering

| Target | | Vacuum | Plating |
|---|---|---|---|
| material | Process gas | degree\Torr | temperature\° C. |
| Aluminum | Argon and oxygen | 10⁻³ to 10⁻² | 240 |
| (AL) | | | |

In step 103, coloring, wherein anodic oxidation coloring is performed to the aluminum-containing metal film.

In the embodiment, an anodic oxidation structure of the aluminum material has a plurality of holes, and color materials enter the holes for coloring, different colors may be obtained from the appearance surface of the ceramic base material through selecting the colors of the color materials in the holes, and a high-quality sample color effect can be achieved. Certainly, other feasible coloring methods by anodic oxidation may also be selected, for example, metal, metal oxide or metal compound is deposited at the bottom of the holes, and various colors are shown due to a scattering effect of electrodeposit to light.

In step 104, an anti-fingerprint plating layer is formed on the surface of the aluminum-containing metal film colored by anodic oxidation.

It can be understood that, the anti-fingerprint plating layer is formed on the surface of the aluminum-containing metal film colored by anodic oxidation through anti-fingerprint processing, and the anti-fingerprint plating layer may effectively prevent fingerprints from being remained on the ceramic piece to affect the sense of beauty.

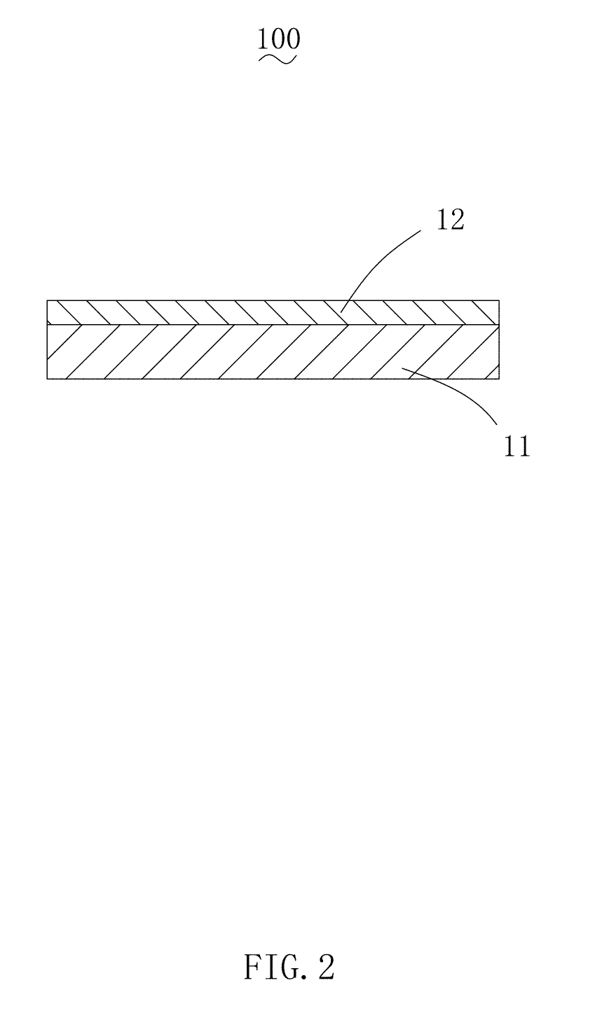

The present disclosure further provides a ceramic piece for electronic products 100. As shown in FIG. 2, the ceramic piece for electronic products 100 comprises: a ceramic base material 11 and an aluminum-containing metal film 12, wherein the aluminum-containing metal film 12 is plated on a surface of the ceramic base material 11, and the aluminum-containing metal film 12 is colored by anodic oxidation.

In the embodiment, preferably, a thickness of the aluminum-containing metal film on the ceramic base material 11 is 30 to 40 μm, and the ceramic base material 11 is made of transparent or semitransparent yttria-stabilized zirconia.

The ceramic piece for electronic products manufactured in the embodiment of the present disclosure not only has a good color effect, but also can well satisfy the requirement of people on the product color, and the product has excellent overall performance, and good practicability and progressiveness. In order to see the superior performances of the ceramic piece for electronic products manufactured by the ceramic coloring method according to the embodiment of the present disclosure more intuitively, partial appearance and performances of the ceramic piece for electronic products are tested by taking blue as an example:

L (luminance), A (red-green) and B (yellow-blue) values of the ceramic piece measured by a colorimeter are respectively as follows: L: 61.17, A: −39.5, and B: −34.34, and the product color is blue.

An adhesive force of the plating layer measured by a cross-cut tester reaches 5B level.

The ceramic piece is rubbed by a steel wool for test, and after rubbing the ceramic piece for 1000 times, the plated film of the ceramic piece is not removed and the color is unchanged.

A pencil hardness test is performed, and the test result is 4H.

In addition, the ceramic piece for electronic products also passes through rubber eraser rubbing and alcohol rubbing tests, high temperature and high humidity tests, cold and hot resistance shock tests, sweat resistance test, and oil resistant test, and all the test results are qualified.

Those skilled in the art can understand that, the embodiments above are detailed embodiments for achieving the disclosure, and various modifications in form and detail can be made on the embodiments during practical application without departing from the spirit and scope of the disclosure.

What is claimed is:

1. A ceramic coloring method, comprising the steps of:
providing a ceramic base material;
plating, wherein an aluminum-containing metal film is plated on a surface of the ceramic base material; and
coloring, wherein anodic oxidation coloring is performed to the aluminum-containing metal film.

2. The ceramic coloring method according to claim 1, wherein the aluminum-containing metal film is made of aluminum or aluminum alloy.

3. The ceramic coloring method according to claim 1, wherein the plating is performed by magnetron sputtering physical vapor deposition.

4. The ceramic coloring method according to claim 1, wherein before the step of plating, the ceramic coloring method further comprises: preprocessing steps of deoiling, neutralizing and washing the provided ceramic base material, a step of baking the preprocessed ceramic base material at a temperature of 150 to 220° C., and a step of performing ionic cleaning to the baked ceramic base material in a vacuum state above 5*10⁻³ Pa.

5. The ceramic coloring method according to claim 4, wherein after completing the step of ionic cleaning, plating is performed in a vacuum state above 5*10⁻⁴ Torr, wherein a plating temperature is 230 to 250° C.

6. The ceramic coloring method according to claim 4, wherein the vacuum state of the step of ionic cleaning is 2*10⁻¹ to 6*10⁻¹ Pa.

7. The ceramic coloring method according to claim 5, wherein the vacuum state of the step of plating is 10⁻³ to 10⁻² Torr.

8. The ceramic coloring method according to claim 1, wherein a thickness of the aluminum-containing metal film is 30 to 40 μm.

9. The ceramic coloring method according to claim 1, wherein before the step of coloring, the ceramic coloring method further comprises: forming an anti-fingerprint plating layer on the surface of the aluminum-containing metal film colored by anodic oxidation.

10. An ceramic piece for electronic products, including: a ceramic base material and an aluminum-containing metal film, wherein the aluminum-containing metal film is plated on a surface of the ceramic base material, and the aluminum-containing metal film is colored by anodic oxidation.

11. The ceramic piece for electronic products according to claim 10, wherein a thickness of the aluminum-containing metal film is 30 to 40 μm.

12. The ceramic piece for electronic products according to claim 10, wherein the ceramic base material is made of yttria-stabilized zirconia.
